(19) United States
(12) Patent Application Publication
(10) Pub. No.: US 2026/0288592 A1
(43) Pub. Date: Sep. 24, 2026

(54) ELECTRONIC DEVICE, RECONFIGURATION METHOD, AND PROGRAM

(71) Applicant: Yokogawa Electric Corporation, Tokyo (JP)

(72) Inventors: Satoshi KAWAI, Tokyo (JP); Kensaku MAEDA, Tokyo (JP)

(21) Appl. No.: 19/470,013

(22) PCT Filed: Mar. 18, 2024
(86) PCT No.: PCT/JP2024/010428

§ 371 Date: Sep. 26, 2025

(30) Foreign Application Priority Data
Mar. 29, 2023 (JP) 2023-053987

(51) Int. Cl. G06F 11/14

(52) U.S. Cl. CPC G06F 11/142

(57) ABSTRACT

An electronic device includes a first memory; a second memory; and a circuitry. The first memory stores therein first configuration data. The second memory to which the first configuration data is loaded. The circuitry is configured to perform user processing that is included in the first configuration data. The circuitry is configured to perform switching to intangible second configuration data in the first memory when a soft error is detected in the second memory while the user processing is being performed. The circuitry is configured to re-road the first configuration data to the second memory by assuming that the switching to the second configuration data is an error.

### TECHNICAL FIELD

The present invention relates to an electronic device, a reconfiguration method, and a program.

### BACKGROUND ART

In recent years, a Distributed Control System (DCS) and a Safety Instrumented System (SIS) are becoming more important in plants. It is often the case that a Field Programmable Gate Array (FPGA) that is an integrated circuit is mounted on various kinds of electronic devices, such as a DCS, an SIS, a communication device, and other Factory Automation (FA) devices, which are used in the plant.

In an FPGA, there is a risk of occurrence of a soft error, such as destruction of data, in a Configuration Random Access Memory (CRAM) that is an internal configuration memory due to disturbance caused by cosmic rays or the like. Therefore, when a logic that needs to be reliable is to be constructed, a countermeasure needs to be taken.

Meanwhile, a vender of an FPGA usually implements a soft error detection function in the FPGA as a standard function. Therefore, for example, a user of an FPGA is able to take a measure, such as mounting an external circuit that, when detecting a soft error signal by the detection function, reconfigures the FPGA by using the signal as a trigger.

### CITATION LIST

### Patent Literature

PTL 1: Japanese Laid-open Patent Publication No. 2014-052781

### SUMMARY OF INVENTION

### Technical Problem

However, in the conventional technology, there is room for improvement in easily and simply solving a soft error without adding an external circuit.

For example, when an external circuit as described above is to be used, the external circuit needs to be mounted on an electronic device in advance. Therefore, for example, it is difficult to apply the conventional technology to an electronic device in which the external circuit is not mounted, which is a problem.

With regard to the problem as described above, it may be possible to adopt a method of exchanging an electronic device with a product including an external circuit to make it possible to apply the conventional technology; however, the number of electronic devices included in a plant is enormous, and this method is not easy even only in terms of costs, such as operating cost, human cost, or expense cost.

An object of the present invention is to provide an electronic device, a reconfiguration method, and a program capable of easily and simply solving a soft error without adding an external circuit.

### Solution to Problem

According to an aspect, an electronic device includes a first storage unit; a second storage unit; a user processing unit; a switching unit; and a loader. The first storage unit stores therein first configuration data. The second storage unit to which the first configuration data is loaded. The user processing unit performs user processing that is included in the first configuration data. The switching unit performs switching to intangible second configuration data in the first storage unit when a soft error is detected in the second storage unit while the user processing is being performed. The loader re-loads the first configuration data to the second storage unit by assuming that the switching to the second configuration data is an error.

According to an aspect, a reconfiguration method is implemented by a computer that includes a first storage unit that stores therein first configuration data, and a second storage unit to which the first configuration data is loaded. The reconfiguration method includes: performing user processing that is included in the first configuration data loaded to the second storage unit; performing switching to intangible second configuration data in the first storage unit when a soft error is detected in the second storage unit while the user processing is being performed; and re-loading the first configuration data to the second storage unit by assuming that the switching to the second configuration data is an error.

According to an aspect, a program causes a computer that includes a first storage unit that stores therein first configuration data, and a second storage unit to which the first configuration data is loaded to execute a process. The process includes: performing user processing that is included in the first configuration data loaded to the second storage unit; performing switching to intangible second configuration data in the first storage unit when a soft error is detected in the second storage unit while the user processing is being performed; and re-loading the first configuration data to the second storage unit by assuming that the switching to the second configuration data is an error.

### Advantageous Effects of Invention

According to one embodiment, it is possible to provide an electronic device, a reconfiguration method, and a program capable of easily and simply solving a soft error without adding an external circuit.

### BRIEF DESCRIPTION OF DRAWINGS

FIG. 1 is a block diagram illustrating a configuration example of an electronic device according to an existing technology.

FIG. 2 is a block diagram illustrating a configuration example of an electronic device according to one embodiment.

FIG. 3 is a diagram for explaining a reconfiguration method according to one embodiment.

FIG. 4 is a flowchart illustrating the flow of a process that is performed by the electronic device according to one embodiment.

FIG. 5 is a hardware configuration diagram illustrating an example of a computer that implements functions of the electronic device according to one embodiment.

### DESCRIPTION OF EMBODIMENTS

Embodiments of an electronic device, a reconfiguration method, and a program disclosed in the present application will be described in detail below based on the drawings. The present invention is not limited by the embodiments below. Further, the same components are denoted by the same reference symbols, repeated explanation will be omitted appropriately, and the embodiments may be combined appropriately as long as no contradiction is derived.

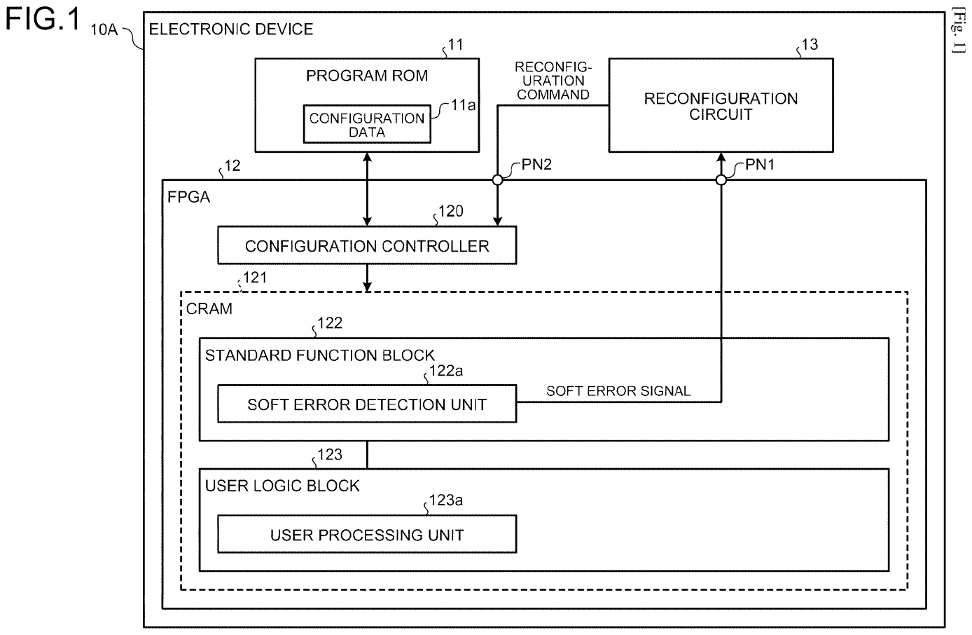

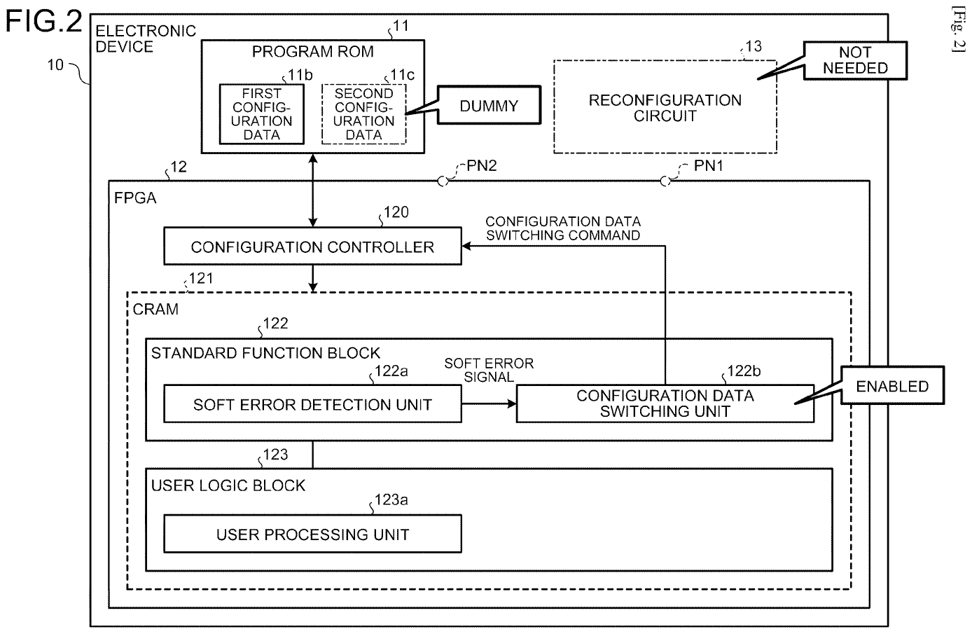

Furthermore, in the following, a case in which an electronic device 10 (see FIG. 2) according to one embodiment include an FPGA 12 (see FIG. 1) will be described as a main example. The FPGA 12 is one example of a Programmable Logic Device (PLC) and is an integrated circuit for which a user is able to reconfigure an internal logic circuit.

The “configuration” indicates that the FPGA 12 loads circuit configuration information (logic and wiring) of a logic circuit from a program Read Only Memory (ROM) 11 (see FIG. 1) to a CRAM 121 (see FIG. 1). In the following, the “configuration” will be appropriately abbreviated as “config”. Accordingly, soft error “re-configuration” will be appropriately abbreviated as “reconfig”. The “reconfiguration” may be read as “reset” or “restart”.

Further, in the following, it is assumed that a reconfiguration method according to one embodiment is a reconfiguration method of the FPGA 12.

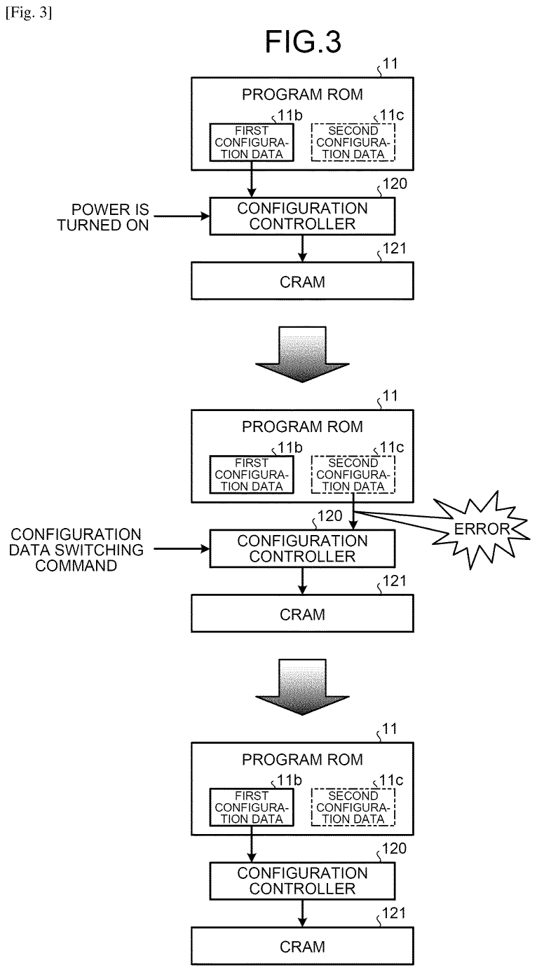

The reconfiguration method according to the present embodiment will be described below with reference to FIG. 1 to FIG. 3. FIG. 1 is a block diagram illustrating a configuration example of an electronic device 10A according to an existing technology. FIG. 2 is a block diagram illustrating a configuration example of the electronic device 10 according to one embodiment. FIG. 3 is a diagram for explaining a reconfiguration method according to one embodiment.

Meanwhile, in FIG. 1 and FIG. 2 corresponding to FIG. 1, only components that are needed to explain the present embodiment are illustrated as functional blocks, and illustration of general components is omitted.

Configuration example of electronic device according to existing technology First, a problem with use of the existing technology will be described in detail below. As illustrated in FIG. 1, the electronic device 10A according to the existing technology includes the program ROM 11, the FPGA 12, and a reconfiguration circuit 13. The program ROM 11, the FPGA 12, and the reconfiguration circuit 13 are implemented on a printed Wired Board (PWB) that is mounted on the electronic device 10A, for example.

The program ROM 11 stores therein configuration data 11a. The configuration data 11a is data that includes circuit configuration information that is to be loaded onto the CRAM 121 of the FPGA 12. The configuration data 11a may be read as “program data”. Meanwhile, a capacity of the program ROM 11 is limited so as to correspond to a single piece of program data of the FPGA 12 from the viewpoint of cost or the like.

The FPGA 12 is, as described above, an integrated circuit for which a user is able to reconfigure an internal logic circuit. The FPGA 12 includes a configuration controller 120, the CRAM 121, a standard function block 122, and a user logic block 123.

The configuration controller 120 corresponds to what is called a “loader”. The configuration controller 120, when power of the electronic device 10A is turned on and the FPGA 12 is activated, performs configuration of reading the configuration data 11a from the program ROM 11 and loading the configuration data 11a to the CRAM 121.

Further, the configuration controller 120, when receiving a reconfiguration command from the reconfiguration circuit 13, performs reconfiguration of re-reading the configuration data 11a from the program ROM 11 and re-loading the configuration data 11a to the CRAM 121.

The CRAM 121 expands the configuration data 11a that includes the circuit configuration information onto a memory image.

The standard function block 122 is a logic block that implements a standard function that is provided by a vender of the FPGA 12. The standard function block 122 includes a soft error detection unit 122a. The soft error detection unit 122a monitors occurrence of a soft error due to disturbance of cosmic rays or the like, and outputs a soft error detection signal when the soft error occurs.

The user logic block 123 is a logic block that can arbitrarily be reconfigured by a user of the FPGA 12. The user logic block 123 includes a user processing unit 123a. The user processing unit 123a performs a process by an algorithm that is arbitrarily written by using Hardware Description Language (HDL) by the user.

Meanwhile, in the existing technology, as a countermeasure against occurrence of the soft error as described above, in some cases, an external circuit is mounted in advance, reconfiguration is performed by causing the external circuit to issue a reconfiguration command by adopting a soft error signal as a trigger, and the soft error is solved.

The reconfiguration circuit 13 corresponds to the external circuit. The reconfiguration circuit 13 is connected to the FPGA 12 via external pins PN1 and PN2. Further, when detecting the soft error, the soft error detection unit 122a outputs the soft error signal to the external pin PN1.

The reconfiguration circuit 13, when receiving the soft error signal via the external pin PN1, issues the reconfiguration command to the external pin PN2 and activates the external pin PN2. Furthermore, when the configuration controller 120 detects activation of the external pin PN2 by the reconfiguration command, the configuration controller 120 re-reads the configuration data 11a from the program ROM 11 and re-loads the configuration data 11a to the CRAM 121.

However, when the reconfiguration circuit 13 is to be used, the reconfiguration circuit 13 needs to be mounted in advance on the electronic device 10A. Therefore, for example, the existing technology is not applicable to an electronic device in which the reconfiguration circuit 13 is not mounted, which is a problem.

To address this problem, it may be possible to adopt a method of exchanging an electronic device with a product including the reconfiguration circuit 13 to make it possible to apply the existing technology; however, the number of electronic devices included in a plant is enormous and it is obvious that the number of communication devices that connect a field side and a measurement side is particularly enormous. Therefore, this method is not easy even only in terms of costs, such as operating cost, human cost, or expense cost.

To cope with this, in the reconfiguration method according to one embodiment, the electronic device 10 that includes the program ROM 11, which stores therein first configuration data, and the CRAM 121, onto which the first configuration data is loaded, performs user processing that is included in the first configuration data loaded on the CRAM 121, and performs a process of switching to intangible second configuration data in the program ROM 11 when a soft error of the CRAM 121 is detected while the user processing is being performed, and re-loading the first configuration data to the CRAM 121 by adopting the switching to the second configuration data as an error.

Configuration example of electronic device according to one embodiment A configuration example of the electronic device 10 according to one embodiment is illustrated in FIG. 2. Meanwhile, FIG. 2 corresponds to FIG. 1, and therefore, a difference from FIG. 1 will be mainly described below.

As illustrated in FIG. 2, the electronic device 10 according to one embodiment is different from the electronic device 10A according to the existing technology in that first configuration data 11b is stored in the program ROM 11 and second configuration data 11c is pretended to be stored in the program ROM 11.

The first configuration data 11b is the same as the configuration data 11a illustrated in FIG. 1. Further, the first configuration data 11b is default configuration data that is firstly loaded to the CRAM 121 when power is turned on.

In contrast, the second configuration data 11c is intangible. The second configuration data 11c is pretended to be stored in the program ROM 11 in setting of a configuration data switching command (to be described later). In other words, the second configuration data 11c is, as illustrated in FIG. 2, “dummy” configuration data.

Furthermore, the electronic device 10 is different from the electronic device 10A according to the existing technology in that the standard function block 122 further includes a configuration data switching unit 122b. The configuration data switching unit 122b performs switching of configuration data, which is one of standard functions provided by the vender of the FPGA 12. In the present embodiment, the configuration data switching unit 122b is “enabled” in advance by a user as illustrated in FIG. 2 so as to be able to implement the function as described above.

The configuration data switching unit 122b is arranged so as to issue a configuration data switching command that is an instruction to switch configuration data to the configuration controller 120 when an arbitrary trigger signal that is designated by the user is input.

In the present embodiment, in the configuration data switching unit 122b, the soft error signal output by the soft error detection unit 122a is designated as a trigger signal in advance by the user. Further, the configuration data switching unit 122b is designated in advance by the user so as to issue the configuration data switching command that is an instruction to switch from the first configuration data 11b to the second configuration data 11c when the soft error signal is input.

With this configuration, in the present embodiment, the configuration data switching unit 122b issues the configuration data switching command that is an instruction to switch from the first configuration data 11b to the second configuration data 11c when the soft error signal is input from the soft error detection unit 122a. The reconfiguration method that is performed by the electronic device 10 configured as described above is illustrated in FIG. 3.

Explanation of reconfiguration method according to one embodiment As illustrated in FIG. 3, in the reconfiguration method according to one embodiment, when power of the electronic device 10 is turned on, the configuration controller 120 of the FPGA 12 performs configuration of loading the first configuration data 11b from the program ROM 11 to the CRAM 121.

Further, when receiving the configuration data switching command from the configuration data switching unit 122b while the electronic device 10 is activated, the configuration controller 120 performs reconfiguration of loading the second configuration data 11c from the program ROM 11 to the CRAM 121.

However, as described above, the second configuration data 11c is dummy data and intangible, and therefore the reconfiguration results in “error”. In the reconfiguration method according to one embodiment, the electronic device 10 is intentionally configured such that reconfiguration on the second configuration data 11c results in error.

Furthermore, if the reconfiguration on the second configuration data 11c results in error, the configuration controller 120 performs reconfiguration of loading the first configuration data 11b that is default data to the CRAM 121. Consequently, according to the reconfiguration method of one embodiment, reconfiguration on the first configuration data 11b is performed with respect to the soft error, so that the first configuration data 11b is re-loaded to the CRAM 121 and the soft error is solved.

In this manner, in the reconfiguration method according to one embodiment, a situation in which reconfiguration on the second configuration data 11c results in error is intentionally created to make it possible to eventually perform reconfiguration on the first configuration data 11b.

Specifically, in the reconfiguration method according to one embodiment, the FPGA 12 is substantially reset by using a configuration data switch algorithm that is not a reset algorithm for resetting the FPGA 12.

Therefore, according to the reconfiguration method of one embodiment, even if the vendor of the FPGA 12 does not provide a reset function as a standard function, it is possible to reset the FPGA 12 by a configuration data switch function as a substitute for the reset function and solve the soft error.

Furthermore, with this configuration, operation of replacing configuration data or ex-changing a product with respect to the existing electronic device 10 in a case where the vendor of the FPGA 12 provides the reset function is not needed.

Referring back to explanation of FIG. 2, according to the reconfiguration method of one embodiment, mounting of the reconfiguration circuit 13 is “not needed” as illustrated in FIG. 2. Furthermore, with this configuration, the external pins PN1 and PN2 need not be used. Therefore, according to the reconfiguration method of one embodiment, the existing electronic device 10 need not be exchanged with a product that includes the reconfiguration circuit 13, so that it is possible to easily and simply solve the soft error.

Moreover, according to the reconfiguration method of one embodiment, the intangible second configuration data 11c is pretended to be stored in the program ROM 11. In other words, in reality, the second configuration data 11c does not use the program ROM 11. Therefore, according to the reconfiguration method of one embodiment, even if the capacity of the program ROM 11 is limited so as to correspond to a single piece of configuration data, it is possible to easily and simply solve the soft error without exchanging the program ROM 11.

Thus, the reconfiguration method according to one embodiment is particularly useful in a plant in which an enormous number of the electronic devices 10 are arranged.

### Flow of Process

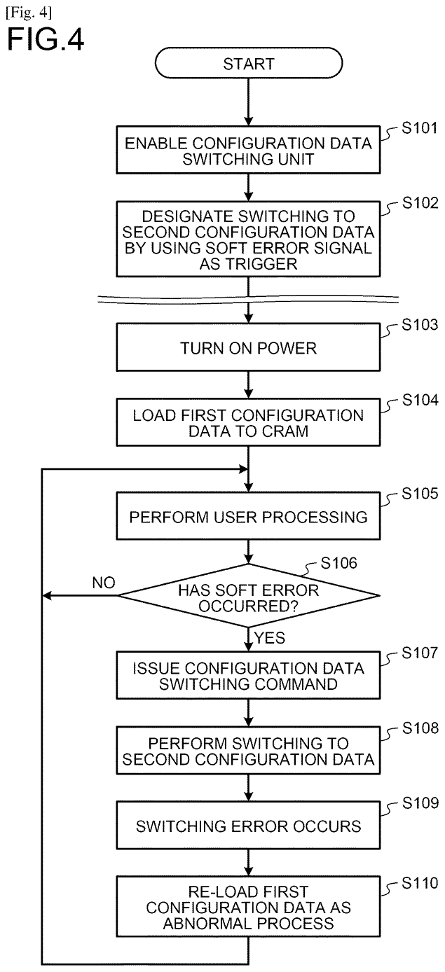

The flow of a process performed by the electronic device 10 according to one embodiment will be described below. FIG. 4 is a flowchart illustrating the flow of a process that is performed by the electronic device 10 according to one embodiment.

As illustrated in FIG. 4, the electronic device 10 first enables the configuration data switching unit 122b in advance in accordance with designation by the user (Step S101). Further, the user designates, with respect to the configuration data switching unit 122b, switching to the second configuration data 11c by using the soft error signal as a trigger (Step S102).

In the state as described above, if power of the electronic device 10 is turned on (Step S103), the electronic device 10 is first loads the first configuration data 11b that is default data to the CRAM 121 (Step S104).

Further, the user processing unit 123a in the electronic device 10 performs user processing (Step S105). While the user processing is being performed, the soft error detection unit 122a monitors occurrence of a soft error (Step S106).

If it is determined that the soft error has occurred (Yes at Step S106), the configuration data switching unit 122b in the electronic device 10 issues the configuration data switching command to the configuration controller 120 (Step S107). In response to this, the configuration controller 120 performs switching to the second configuration data 11c (Step S108).

However, the second configuration data 11c is intangible dummy configuration data, and therefore, a switching error occurs (Step S109).

Accordingly, the configuration controller 120 in the electronic device 10 re-loads the first configuration data 11b as an abnormal process (Step S110). Consequently, the electronic device 10 solves the soft error. Further, the electronic device 10 repeats the process from Step S105.

Furthermore, if the soft error has not occurred at Step S106 (No at Step S106), the electronic device 10 repeats the process from Step S105.

### Effects

As described above, the electronic device 10 according to one embodiment includes the program ROM 11 (corresponding to one example of a “first storage unit”), the CRAM 121 (corresponding to one example of a “second storage unit”), the user processing unit 123a, the configuration data switching unit 122b, and the configuration controller 120 (corresponding to one example of a “loader”). The program ROM 11 stores therein the first configuration data 11b. The first configuration data 11b is loaded to the CRAM 121. The user processing unit 123a performs user processing that is included in the first configuration data 11b. The configuration data switching unit 122b performs switching to the intangible second configuration data 11c in the program ROM 11 when a soft error is detected in the CRAM 121 while the user processing as described above is being performed. The configuration controller 120 re-loads the first configuration data 11b to the CRAM 121 by assuming that the switching to the second configuration data 11c is an error. Therefore, according to the electronic device 10 of one embodiment, it is possible to easily and simply solve the soft error without adding the reconfiguration circuit 13 (corresponding to one example of an “external circuit”).

Furthermore, the capacity of the program ROM 11 corresponds to a single piece of configuration data. Therefore, according to the electronic device 10 of one embodiment, even if the capacity of the program ROM 11 is limited so as to correspond to a single piece of configuration data, it is possible to easily and simply solve the soft error without exchanging the program ROM 11 by assuming that the intangible second configuration data 11c is pretended to be present.

Moreover, the electronic device 10 includes a programmable logic device. The programmable logic device includes the CRAM 121, the user processing unit 123a, the configuration data switching unit 122b, and the configuration controller 120. Therefore, according to the electronic device 10 of one embodiment, when the programmable logic device, such as a Programmable Array Logic (PAL), Generic Array Logic (GAL), Complex Programmable Logic Device (CPLD), or the FPGA 12, is mounted, it is possible to easily and simply solve the soft error without adding the re-configuration circuit 13.

Furthermore, the configuration data switching unit 122b is enabled in advance to allow switching between the first configuration data 11b and the second configuration data 11c. Therefore, according to the electronic device 10 of one embodiment, by using switching of the configuration data that is a standard function of the FPGA 12, it is possible to easily and simply solve the soft error without adding the reconfiguration circuit 13.

Moreover, the configuration data switching unit 122b is able to issue the configuration data switching command (corresponding to one example of a “switching command”) to the configuration controller 120 by designation of an arbitrary trigger signal, and is set in advance so as to issue the configuration data switching command that is an instruction to switch to the second configuration data 11c to the configuration controller 120 when a soft error signal is input upon detection of the soft error. Therefore, according to the electronic device 10 of one embodiment, a situation in which reconfiguration on the second configuration data 11c results in error is intentionally created to make it possible to eventually perform reconfiguration on the first configuration data 11b. In other words, the electronic device 10 according to one embodiment substantially resets the FPGA 12 by using a configuration data switch algorithm that is not a reset algorithm for resetting the FPGA 12. Therefore, according to the electronic device 10 of one embodiment, even if the vendor of the FPGA 12 does not provide a reset function as a standard function, it is possible to reset the FPGA 12 by a configuration data switch function as a substitute for the reset function and solve the soft error.

Furthermore, the programmable logic device as described above is the FPGA 12. Therefore, according to the electronic device 10 of one embodiment, when the FPGA 12 is mounted, it is possible to easily and simply solve the soft error without adding the reconfiguration circuit 13.

Moreover, the electronic device 10 is arranged in a plant. Therefore, according to the electronic device 10 of one embodiment, in a plan in which an enormous number of the electronic devices 10 are arranged, it is possible to easily and simply solve the soft error without adding the reconfiguration circuit 13.

Furthermore, the electronic device 10 is arranged as a communication device of the plant. Therefore, according to the electronic device 10 of one embodiment, with respect to the communication devices, the number of which arranged in the plant is larger than other devices, it is possible to easily and simply solve the soft error without adding the reconfiguration circuit 13.

Moreover, the reconfiguration method according to one embodiment is implemented by the electronic device 10 (corresponding to one example of a “computer”) that includes the program ROM 11 that stores therein the first configuration data 11b and the CRAM 121 to which the first configuration data 11b is loaded, and includes a process of performing user processing that is included in the first configuration data 11b, a process of performing switching to the intangible second configuration data 11c in the program ROM 11 when a soft error is detected in the CRAM 121 while the user processing is being performed, and a process of re-loading the first configuration data 11b to the CRAM 121 by assuming that the switching to the second configuration data 11c is an error. Therefore, according to the reconfiguration method of one embodiment, it is possible to easily and simply solve the soft error without adding the re-configuration circuit 13.

Furthermore, a program according to one embodiment causes the electronic device 10 (corresponding to one example of a “computer”), which includes the program ROM 11 that stores therein the first configuration data 11b and the CRAM 121 to which the first configuration data 11b is loaded, to perform a process of performing the user processing that is included in the first configuration data 11b, a process of performing switching to the intangible second configuration data 11c in the program ROM 11 when a soft error is detected in the CRAM 121 while the user processing is being performed, a process of determining that the switching to the second configuration data 11c is an error, and a process of re-loading the first configuration data 11b to the CRAM 121. Therefore, according to the program of one embodiment, it is possible to easily and simply solve the soft error without adding the reconfiguration circuit 13.

Moreover, according to the program of one embodiment, an additional element for implementing the program is closed inside the FPGA 12, so that it is possible to apply the program to the existing electronic device 10 by addition at a later time (reconfiguration of the internal logic circuit of the FPGA 12).

### Other embodiments

While embodiments of the present invention have been described above, the present invention may be embodied in various different forms other than the embodiments as described above.

### System

The processing procedures, control procedures, specific names, and information including various kinds of data and parameters illustrated in the above-described document and drawings may be arbitrarily changed unless otherwise specified.

Further, the components of the devices illustrated in the drawings are functionally conceptual and do not necessarily have to be physically configured in the manner illustrated in the drawings. In other words, specific forms of distribution and integration of the devices are not limited to those illustrated in the drawings, and all or component of the devices may be functionally or physically distributed or integrated in arbitrary units depending on various loads or use conditions.

Furthermore, for each processing function performed by each device, all or any component of the processing function may be implemented by a Central Processing Unit (CPU) and a program analyzed and executed by the CPU or may be implemented as hardware by wired logic.

### Hardware

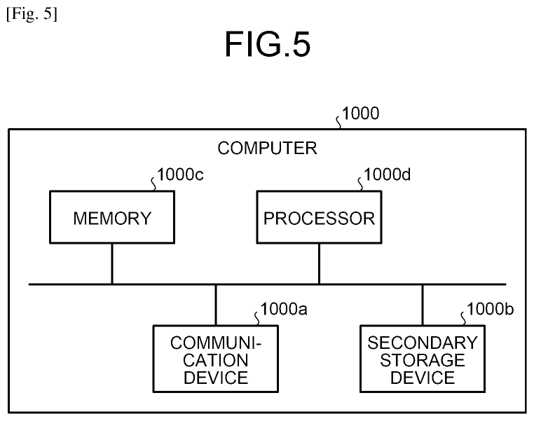

The electronic device 10 according to one embodiment as described above is implemented by, for example, a computer 1000 that is configured as illustrated in FIG. 5. FIG. 5 is a hardware configuration diagram illustrating an example of the computer 1000 that implements the electronic device 10 according to one embodiment.

As illustrated in FIG. 5, the computer 1000 includes a communication device 1000a, a secondary storage device 1000b, a memory 1000c, and a processor 1000d. Further, all of the units illustrated in FIG. 5 are connected to one another via a bus or the like.

The communication device 1000a is a Network Interface Card (NIC) or the like and communicates with a different device. The secondary storage device 1000b is implemented by a flash memory, a Hard Disk Drive (HDD), or the like, and stores therein a program that implements the functions illustrated in FIG. 2 and a database.

The processor 1000d reads a program that implements the same process as that of each of the processing units illustrated in FIG. 2 from the secondary storage device 1000b or the like, loads the program onto the memory 1000c, and executes a thread for implementing each of the functions illustrated in FIG. 2 or the like. For example, the thread implements the same function as that of each of the processing units included in the electronic device 10. Specifically, the processor 1000d reads a program that has the same function as that of each of the functional blocks included in the FPGA 12 from the secondary storage device 1000b or the like. Further, the processor 1000d executes a thread that implements the same process as that of each of the functional blocks included in the FPGA 12.

As described above, the computer 1000 operates as an electronic device that performs various kinds of processing methods by reading and executing the program. Further, the computer 1000 may implement the same functions as those of the embodiment as described above by causing a medium reading device to read the above-described program from a recording medium and executes the read program. Meanwhile, the program described herein need not always be executed by the computer 1000. For example, the present invention is similarly applicable when a computer or a server that has a different hardware configuration executes the program or when the computer and the server execute the program in a cooperative manner.

The program m may be distributed via a network, such as the Internet. Furthermore, the program may be recorded in a computer readable recording medium, such as an HDD, a flexible disk (FD), a compact disc (CD)-ROM, a Magneto-Optical disk (MO), or a Digital Versatile Disc (DVD), and may be read from the recording medium and executed by a computer. The recording medium in which the program is recorded is one embodiment of the present disclosure.

### Others

Examples of combinations of disclosed features will be described below.

(1)

An electronic device comprising
a first storage unit that stores therein first configuration data;
a second storage unit to which the first configuration data is loaded;
a user processing unit that performs user processing that is included in the first configuration data;
a switching unit that performs switching to intangible second configuration data in the first storage unit when a soft error is detected in the second storage unit while the user processing is being performed; and
a loader that re-loads the first configuration data to the second storage unit by assuming that the switching to the second configuration data is an error.
   (2)

The electronic device according to (1), wherein a capacity of the first storage unit corresponds to a single piece of configuration data.

(3)

The electronic device according to (1) or (2), further comprising:
a programmable logic device, wherein
the programmable logic device includes the second storage unit, the user processing unit, the switching unit, and the loader.
   (4)

The electronic device according to (3), wherein the switching unit is enabled in advance to allow switching between the first configuration data and the second configuration data.

(5)

The electronic device according to (3) or (4), wherein the switching unit is able to issue a switching command to the loader by designation of an arbitrary trigger signal, and is set in advance so as to issue the switching command that is an instruction to switch to the second configuration data to the loader when a soft error signal is input upon detection of the soft error.

(6)

The electronic device according to (3), (4), or (5), wherein the programmable logic device is a Field Programmable Gate Array (FPGA).

(7)

The electronic device according to any one of (1) to (6), wherein the electronic device is arranged in a plant.

(8)

The electronic device according to (7), wherein the electronic device is arranged as a communication device in the plant.

(9)

A reconfiguration method that is implemented by a computer that includes
a first storage unit that stores therein first configuration data; and
a second storage unit to which the first configuration data is loaded,
the reconfiguration method comprising:
performing user processing that is included in the first configuration data loaded to the second storage unit;
performing switching to intangible second configuration data in the first storage unit when a soft error is detected in the second storage unit while the user processing is being performed; and
re-loading the first configuration data to the second storage unit by assuming that the switching to the second configuration data is an error.
   (10)

A program that causes a computer that includes
a first storage unit that stores therein first configuration data; and
a second storage unit to which the first configuration data is loaded, to execute a process comprising:
performing user processing that is included in the first configuration data loaded to the second storage unit;
performing switching to intangible second configuration data in the first storage unit when a soft error is detected in the second storage unit while the user processing is being performed; and
re-loading the first configuration data to the second storage unit by assuming that the switching to the second configuration data is an error.
   (11)

A non-transitory computer-readable storage medium having stored therein a program that causes a computer including
a first storage unit that stores therein first configuration data; and
a second storage unit to which the first configuration data is loaded, to execute a process comprising:
performing user processing that is included in the first configuration data loaded to the second storage unit;
performing switching to intangible second configuration data in the first storage unit when a soft error is detected in the second storage unit while the user processing is being performed;
re-loading the first configuration data to the second storage unit by assuming that the switching to the second configuration data is an error.

### REFERENCE SIGNS LIST

10, 10A Electronic device
11 Program ROM
11a Configuration data
11b First configuration data
11c Second configuration data
12 FPGA
13 Reconfiguration circuit
120 Configuration controller
121 CRAM
122 Standard function block
122a Soft error detection unit
122b Configuration data switching unit
123 User logic block
123a User processing unit

1. An electronic device comprising
a first memory that stores therein first configuration data;
a second memory to which the first configuration data is loaded; and
a circuitry configured to:
perform user processing that is included in the first configuration data;
perform switching to intangible second configuration data in the first memory when a soft error is detected in the second memory while the user processing is being performed; and
re-load the first configuration data to the second storage unit second memory by assuming that the switching to the second configuration data is an error.

2. The electronic device according to claim 1, wherein a capacity of the first memory corresponds to a single piece of configuration data.

3. The electronic device according to claim 1, further comprising:
a programmable logic device, wherein
the programmable logic device includes the second memory, and the circuitry.

4. The electronic device according to claim 3, wherein the circuitry is enabled in advance to allow switching between the first configuration data and the second configuration data.

5. The electronic device according to claim 3, wherein the circuitry is able to issue a switching command to the circuitry by designation of an arbitrary trigger signal, and is set in advance so as to issue the switching command that is an instruction to switch to the second configuration data to the circuitry when a soft error signal is input upon detection of the soft error.

6. The electronic device according to claim 3, wherein the programmable logic device is a Field Programmable Gate Array (FPGA).

7. The electronic device according to claim 1, wherein the electronic device is arranged in a plant.

8. The electronic device according to claim 7, wherein the electronic device is arranged as a communication device in the plant.

9. A reconfiguration method that is implemented by a computer that includes
a first memory that stores therein first configuration data; and
a second memory to which the first configuration data is loaded,
the reconfiguration method comprising:
performing user processing that is included in the first configuration data loaded to the second memory;
performing switching to intangible second configuration data in the first memory when a soft error is detected in the second memory while the user processing is being performed; and
re-loading the first configuration data to the second memory by assuming that the switching to the second configuration data is an error.

10. A non-transitory computer-readable recording medium having stored therein a program that causes a computer that includes
a first memory that stores therein first configuration data; and
a second memory to which the first configuration data is loaded, to execute a process comprising:
performing user processing that is included in the first configuration data loaded to the second memory;
performing switching to intangible second configuration data in the first memory when a soft error is detected in the second memory while the user processing is being performed; and
re-loading the first configuration data to the second memory by assuming that the switching to the second configuration data is an error.
